(19) United States
(12) Patent Application Publication
(10) Pub. No.: US 2016/0226013 A1
(43) Pub. Date: Aug. 4, 2016

(54) Organic Light-Emitting Diode Displays with Tilted and Curved Pixels

(71) Applicant: Apple Inc., Cupertino, CA (US)

(72) Inventors: Rui Liu, San Jose, CA (US); Cheng Chen, San Jose, CA (US); Jae Won Choi, Cupertino, CA (US); Kwang Ohk Cheon, Sunnyvale, CA (US); Meng-Huan Ho, Hsinchu City (TW); Young Bae Park, San Jose, CA (US)

(21) Appl. No.: 14/608,897

(22) Filed: Jan. 29, 2015

(51) Int. Cl. H01L 51/52; H01L 51/56; H01L 27/32

(52) U.S. Cl. CPC H01L 51/5209; H01L 27/3258; H01L 27/3248; H01L 51/56; H01L 2227/323

(57) ABSTRACT

A display may have thin-film transistor circuitry on a substrate with a substrate surface. An array of organic light-emitting diodes may be formed on the thin-film transistor circuitry. The organic light-emitting diodes may have anodes, cathodes, and emissive material located between the anodes and cathodes. The anodes may be oriented so that they are not parallel to the substrate surface. The anodes may have curved shapes or may have tilted shapes. Tilted anodes may have multiple segments. Anodes may be tilted by amounts that vary as a function of lateral distance across a display.

### BACKGROUND

This relates generally to electronic devices with displays, and, more particularly, to organic light-emitting diode displays.

Electronic devices often include displays. Displays such as organic light-emitting diode displays have pixels with light-emitting diodes. The light emitting diodes each have electrodes (i.e., an anode and a cathode). Emissive material is interposed between the electrodes. During operation, current passes between the electrodes through the emissive material, generating light.

The electrodes in an organic light-emitting diode display are formed from a photolithographically patterned layer of conductive material such as indium tin oxide and/or metal. Unlike other conductive structures in a display such as signal lines that may be covered with opaque masking material, the light-emitting diode electrodes are exposed. The electrodes may therefore give rise to strong specular light reflections. This may cause ambient light to be reflected towards a viewer. These reflections can make it difficult to view images on the display. Ambient light reflections may be suppressed by covering a display with a circular polarizer, but use of a circular polarizer can significantly reduce light emission efficiency. In some organic light-emitting diode displays, microcavity structures have been used to enhance on-axis efficiency and reduce power consumption. This type of microcavity structure requires optimized organic layer thicknesses with proper electrode reflectivity. Such microcavities will typically result in significant off-axis intensity reductions and color shifts.

It would therefore be desirable to be able to provide organic light-emitting diode displays with enhanced specular reflection characteristics and reduced off-axis color and intensity shifts.

### SUMMARY

An organic light-emitting diode display may have an array of light-emitting diodes that form an array of pixels. The array of pixels may be used to display images for a viewer. Each light-emitting diode may have a layer of emissive material interposed between an anode and a cathode. When current is passed between the anode and the cathode through the emissive material, the light-emitting diode will emit light.

Thin-film transistor circuitry may be used to form pixel circuits that control the current applied through the light-emitting diode of each pixel. The thin-film transistor circuitry may include transistors and thin-film capacitors and may be formed from semiconductor layers, dielectric layers, and metal layers on a substrate.

The substrate on which the thin-film transistor circuitry is formed has a surface. The electrodes that are formed for the light-emitting diodes may have surfaces that are not parallel to the surface of the substrate. The anodes may, for example, have curved surfaces or may have surfaces that are tilted with respect to the surface of the substrate. Tilted anodes may be tilted by an amount that varies across the surface of the display to enhance viewing characteristics for wide displays. Segmented anodes may be provided that have multiple tilted portions joined by connecting portions. Curved and tilted anodes may be used to redirect specular reflections away from a viewer and may help reduce off-axis intensity and color shifts.

Anodes that are tilted or curved may be formed by using grayscale masks to fabricate tilted or curved depressions in underlying layers in the thin-film transistor circuitry. Anodes may also be tilted or curved by incorporating tilt-inducing structures such as metal layers into portions of the thin-film transistor circuitry under the anodes. Metal layers or other tilt-inducing structures may, as an example, be formed under a thin polymer layer that becomes tilted due to the presence of the tilt-inducing structures.

### BRIEF DESCRIPTION OF THE DRAWINGS

FIG. 1 is a schematic diagram of an illustrative electronic device having a display in accordance with an embodiment.

FIG. 2 is a top view of an illustrative display in an electronic device in accordance with an embodiment.

FIG. 3 is a cross-sectional side view of a portion of an illustrative organic light-emitting diode display in accordance with an embodiment.

FIG. 4 is cross-sectional side view of a portion of an illustrative organic light-emitting diode display with tilted anodes in accordance with an embodiment.

FIG. 5 is a diagram showing how the direction of specular reflections from a display may be adjusted by tilting anodes in the display by an appropriate amount in accordance with an embodiment.

FIG. 6 is a diagram showing how anodes in a display may be tilted by different amounts as a function of lateral position across the surface of the display in accordance with an embodiment.

FIG. 7 is a cross-sectional side view of an illustrative organic light-emitting diode display with curved anodes in accordance with an embodiment.

FIG. 8 is a top view of a portion of an illustrative organic light-emitting diode display showing how pixels of different colors may be arranged on the surface of the display in accordance with an embodiment.

FIG. 9 is a cross-sectional side view of a pixel in the illustrative organic light-emitting diode display of FIG. 8 showing how pixels may be provide with tilted anodes that are divided into multiple smaller sections to avoid creating excessive height differences between the edges of the anodes in accordance with an embodiment.

FIG. 10 is a cross-sectional side view of a portion of an illustrative organic light-emitting diode display with an anode that has been tilted due to the presence of a portion of a source-drain metal layer under a polymer layer that supports the anode in accordance with an embodiment.

FIG. 11 is a cross-sectional side view of a portion of an illustrative organic light-emitting diode display with an anode that has been tilted due to the presence of a portion of an underlying metal layer located above a portion of a source-drain metal layer and a supplemental planarization layer in accordance with an embodiment.

### DETAILED DESCRIPTION

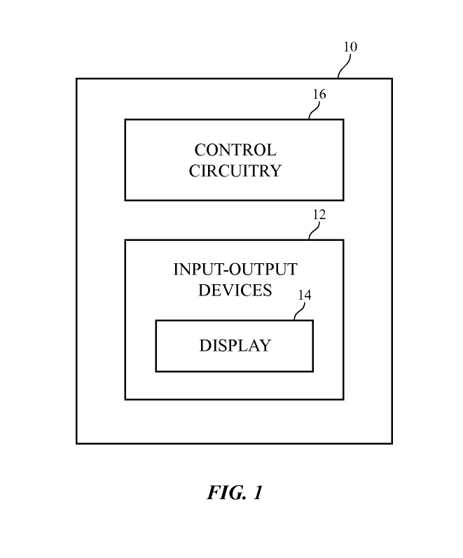

An illustrative electronic device of the type that may be provided with a display is shown in FIG. 1. As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Control circuitry 16 may be used to run software on device 10 such as operating system code and applications. During operation of device 10, the software running on control circuitry 16 may display images on display 14 using an array of pixels in display 14.

Device 10 may be a tablet computer, laptop computer, a desktop computer, a display, a cellular telephone, a media player, a wristwatch device or other wearable electronic equipment, or other suitable electronic device.

Display 14 may be an organic light-emitting diode display or may be a display based on other types of display technology. Configurations in which display 14 is an organic light-emitting diode display are sometimes described herein as an example. This is, however, merely illustrative. Any suitable type of display may be used, if desired.

Display 14 may have a rectangular shape (i.e., display 14 may have a rectangular footprint and a rectangular peripheral edge that runs around the rectangular footprint) or may have other suitable shapes. Display 14 may be planar or may have a curved profile.

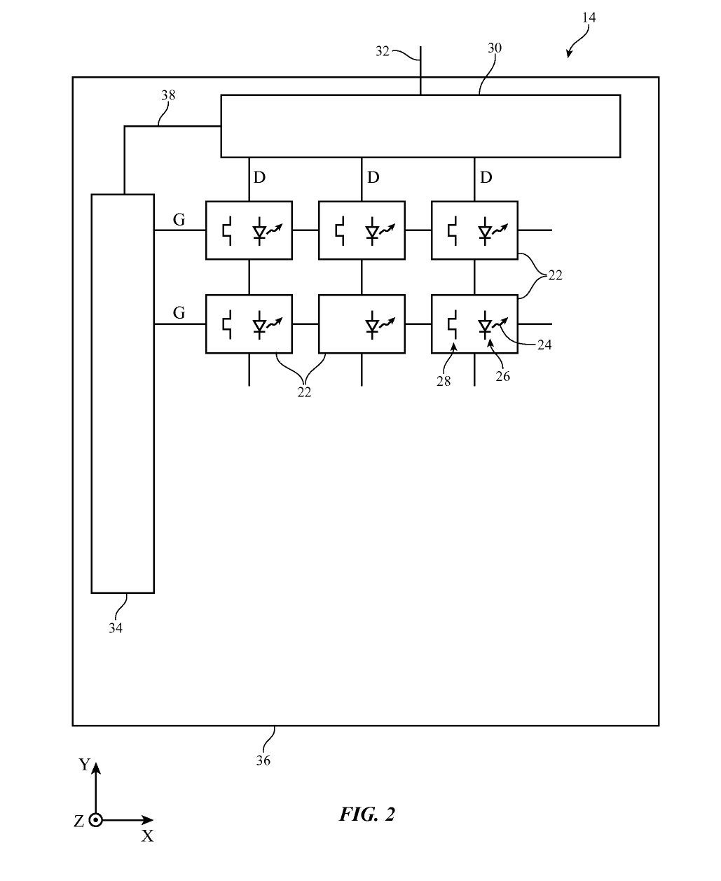

A top view of a portion of display 14 is shown in FIG. 2. As shown in FIG. 2, display 14 may have an array of pixels 22 formed on substrate 36. Substrate 36 may be formed from glass, metal, plastic, ceramic, or other substrate materials. Pixels 22 may receive data signals over signal paths such as data lines D and may receive one or more control signals over control signal paths such as horizontal control lines G (sometimes referred to as gate lines, scan lines, emission control lines, etc.). There may be any suitable number of rows and columns of pixels 22 in display 14 (e.g., tens or more, hundreds or more, or thousands or more). Each pixel 22 may have a light-emitting diode 26 that emits light 24 under the control of a pixel control circuit formed from thin-film transistor circuitry such as thin-film transistors 28 and thin-film capacitors). Thin-film transistors 28 may be polysilicon thin-film transistors, semiconducting-oxide thin-film transistors such as indium zinc gallium oxide transistors, or thin-film transistors formed from other semiconductors. Pixels 22 may contain light-emitting diodes of different colors (e.g., red, green, and blue) to provide display 14 with the ability to display color images.

Display driver circuitry may be used to control the operation of pixels 22. The display driver circuitry may be formed from integrated circuits, thin-film transistor circuits, or other suitable circuitry. Display driver circuitry 30 of FIG. 2 may contain communications circuitry for communicating with system control circuitry such as control circuitry 16 of FIG. 1 over path 32. Path 32 may be formed from traces on a flexible printed circuit or other cable. During operation, the control circuitry (e.g., control circuitry 16 of FIG. 1) may supply circuitry 30 with information on images to be displayed on display 14.

To display the images on display pixels 22, display driver circuitry 30 may supply image data to data lines D while issuing clock signals and other control signals to supporting display driver circuitry such as gate driver circuitry 34 over path 38. If desired, circuitry 30 may also supply clock signals and other control signals to gate driver circuitry on an opposing edge of display 14.

Gate driver circuitry 34 (sometimes referred to as horizontal control line control circuitry) may be implemented as part of an integrated circuit and/or may be implemented using thin-film transistor circuitry. Horizontal control lines G in display 14 may carry gate line signals (scan line signals), emission enable control signals, and other horizontal control signals for controlling the pixels of each row. There may be any suitable number of horizontal control signals per row of pixels 22 (e.g., one or more, two or more, three or more, four or more, etc.).

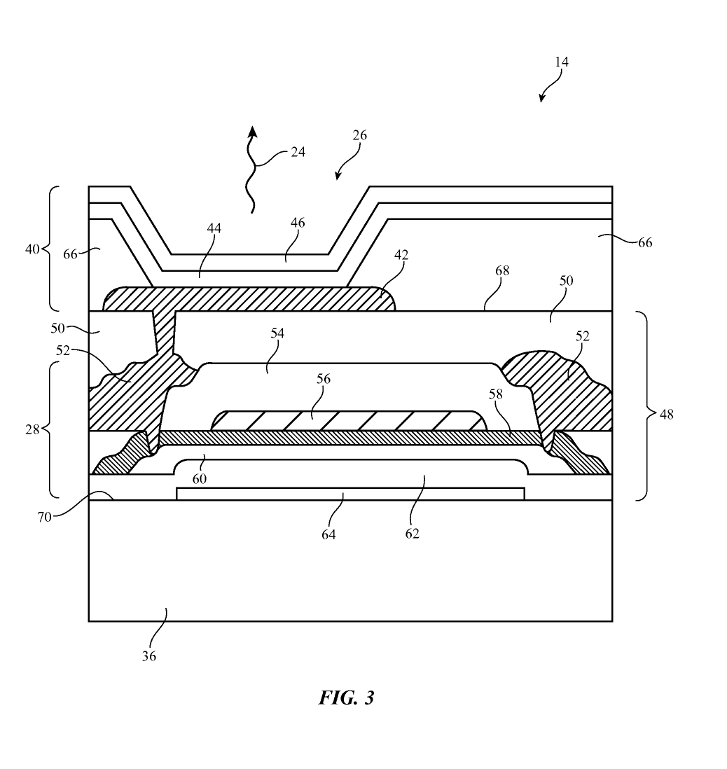

A cross-sectional side view of an illustrative organic light-emitting diode display is shown in FIG. 3. As shown in FIG. 3, display 14 may include a substrate layer such as substrate layer 36. Substrate 36 may be a planar layer or a non-planar layer and may be formed from plastic, glass, ceramic, sapphire, metal, or other suitable materials. The surface of substrate 36 may, if desired, be covered with one or more buffer layers (e.g., inorganic buffer layers such as layers of silicon oxide, silicon nitride, etc.).

Thin-film transistor circuitry 48 may be formed on substrate 36. Thin film transistor circuitry 48 may include transistors, capacitors, and other thin-film structures. As shown in FIG. 3, a transistor such as transistor 28 may be formed from thin-film semiconductor layer 60 in thin-film transistor layers 48. Semiconductor layer 60 may be a polysilicon layer, a semiconducting-oxide layer such as a layer of indium gallium zinc oxide, or other semiconductor layer. Gate layer 56 may be a conductive layer such as a metal layer that is separated from semiconductor layer 60 by an intervening layer of dielectric such as dielectric 58 (e.g., an inorganic gate insulator layer such as a layer of silicon oxide). Dielectric 62 may also be used to separate semiconductor layer 60 from underlying structures such as shield layer 64 (e.g., a shield layer that helps shield the transistor formed from semiconductor layer 60 from charge in buffer layers on substrate 36).

Semiconductor layer 60 of transistor 28 may be contacted by source and drain terminals formed from source-drain metal layer 52. Dielectric layer 54 (e.g., an inorganic dielectric layer) may separate gate metal layer 56 from source-drain metal layer 52. Source-drain metal layer 52 may be shorted to anode 42 of light-emitting diode 26 using a metal via that passes through dielectric planarization layer 50. Planarization layer 50 may be formed from an organic dielectric material such as a polymer.

Light-emitting diode 26 is formed from light-emitting diode layers 40 on thin-film transistor layers 48. Each light-emitting diode has a lower electrode and an upper electrode. In a top emission display, the lower electrode may be formed from a reflective conductive material such as patterned metal to help reflect light that is produced by the light-emitting diode in the upwards direction out of the display. The upper electrode (sometimes referred to as the counter electrode) may be formed from a transparent or semi-transparent conductive layer (e.g., a thin layer of transparent or semitransparent metal and/or a layer of indium tin oxide or other transparent conductive material). This allows the upper electrode to transmit light outwards that has been produced by emissive material in the diode. In a bottom emission display, the lower electrode may be transparent (or semi-transparent) and the upper electrode may be reflective.

In configurations in which the anode is the lower electrode, layers such as a hole injection layer, hole transport layer, emissive material layer, and electron transport layer may be formed above the anode and below the upper electrode, which serves as the cathode for the diode. In inverted configurations in which the cathode is the lower electrode, layers such as an electron transport layer, emissive material layer, hole transport layer, and hole injection layer may be stacked on top of the cathode and may be covered with an upper layer that serves as the anode for the diode. Both electrodes may reflect light.

In general, display 14 may use a configuration in which the anode electrode is closer to the display substrate than the cathode electrode or a configuration in which the cathode electrode is closer to the display substrate than the anode electrode. In addition, both bottom emission and top emission arrangements may be used. Top emission display configurations in which the anode is located on the bottom and the cathode is located on the top are sometimes described herein as an example. This is, however, merely illustrative. Any suitable display arrangement may be used, if desired.

In the illustrative configuration of FIG. 3, display 14 has a top emission configuration and lower electrode 42 is an anode and upper electrode 46 is a cathode. Layers 40 include a patterned metal layer that forms anodes such as anode 42. Anode 42 is formed within an opening in pixel definition layer 66. Pixel definition layer 66 may be formed from a patterned photoimageable polymer. In each light-emitting diode, organic emissive material 44 is interposed between a respective anode 42 and cathode 46. Anodes 42 may be patterned from a layer of metal on thin-film transistor layers 48 such as planarization layer 50. Cathode 46 may be formed from a common conductive layer that is deposited on top of pixel definition layer 66. Cathode 46 is transparent so that light 24 may exit light emitting diode 26 as current is flowing through emissive material 44 between anode 42 and cathode 46.

In the illustrative configuration of FIG. 3, surface 68 of planarization layer 50 is flat and is parallel to surface 70 of substrate 36. Anode 42 and the other layers of light-emitting diode layers 40 are therefore not tilted with respect to substrate 36.

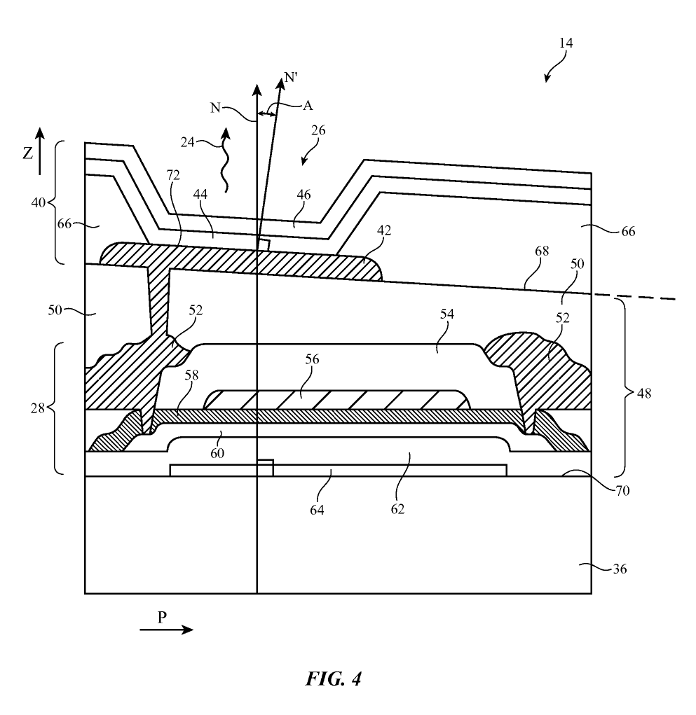

In the illustrative configuration of FIG. 4, planarization dielectric layer 50 has a thickness that varies as a function of lateral distance P along the surface of display 14 under diode 26. As a result, surface 68 of planarization layer 50 in thin-film transistor circuitry 48 is tilted with respect to surface 70 of substrate 36. Anode 42 is formed on surface 68 of planarization layer 50, so the tilted orientation of planarization layer surface 68 causes anode 42 to tilt with respect to substrate surface 70.

Substrate surface 70 of substrate 36 may be planar and may be characterized by surface normal N (i.e., a surface normal that is oriented parallel to outwardly extending dimension Z in the example of FIG. 4). Anode 42 of FIG. 4 has upper surface 72. Anode surface 72 is planar and may be characterized by surface normal N′. Because dielectric layer 50 has a tilted (angled) surface that is not parallel to surface 70, anode surface normal N′ is oriented at a non-zero angle A with respect to substrate surface normal N. Angle A may be 1-40°, 2-30°, 5-30°, 10-30°, 15-25°, more than 5°, more than 15°, less than 30°, or other suitable non-zero angle.

It may be desirable to incorporate display 14 into a device environment with an ambient light source. The ambient light source may be, for example, overhead lighting in an indoor environment, lighting from a laptop computer screen, or other light source. The ambient light source may produce light that has the potential to reflect directly into the eyes of a viewer. By tilting anodes 42 at an appropriate angle A as shown in FIG. 4, the reflected ambient light can be directed away from the viewer, so that images on the display are not obscured. The angular intensity of output light from the pixels of display 14 tends to gradually decrease with increasing angle, so an additional benefit of tilting anodes 42 is that this will tend to direct a higher emitting intensity into the eyes of the viewer.

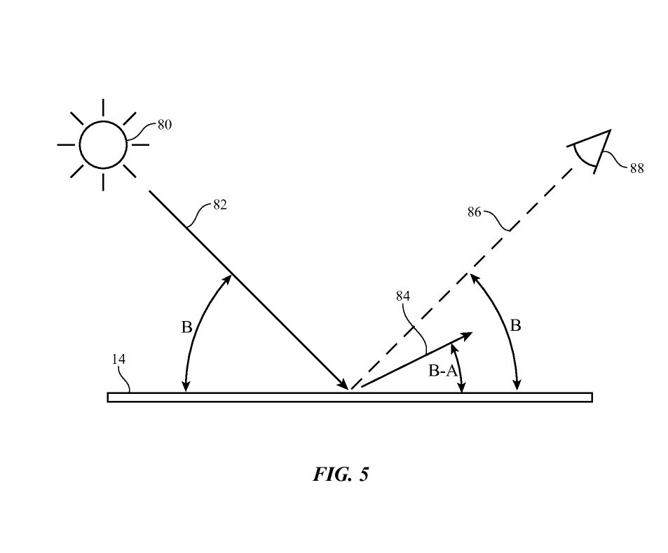

Consider, as an example, the configuration of FIG. 5. As shown in FIG. 5, ambient light source 80 may emit ambient light 82. Display 14 is lying in a horizontal plane in the illustrative arrangement of FIG. 5 and viewer 88 is viewing the surface of display 14 at an angle B of about 45°, giving rise to the possibility that ambient light 82 will reflect from the anodes on the surface of display 14 into the eyes of viewer 88 (see, e.g., possible reflected ambient light ray 86). This type of layout may arise, for example, in a configuration in which device 10 is a laptop computer, light source 80 is a display mounted in the upper portion of a hinged laptop housing, and display 14 is an ancillary display located in the lower portion of the hinged laptop housing adjacent to the function keys of the laptop computer. This type of layout may also arise in other configurations (e.g., when display 14 is being used as part of a sign or other stationary display and when ambient light source 80 is part of a stationary indoor lighting system). Viewer 88 may also view display 14 at different angles and light source 80 may be located in different positions relative to display 14. The example of FIG. 5 in which display 14 is being viewed at a 45° angle so that light 82 has the potential to reflect towards viewer 88 as light 86 is merely illustrative.

When display 14 is operating, images will be present on display 14. Viewer 88 may desire to view the content being displayed by display 14. If care is not taken, specular reflections from the anodes of display 14 may cause reflected ambient light 86 to shine into the eyes of viewer 88 and obscure the image being displayed on display 14. To prevent this from occurring, anodes 42 may be tilted at a non-zero angle A with respect to substrate 36. For example, anodes 42 may be tilted towards viewer 88 by angle A. When anodes 42 are tilted in this way, ambient light 82 will reflect from tilted anodes 42 in the direction of reflected light ray 84 rather than in the direction of reflected light ray 86. As shown in FIG. 5, reflected light ray 84 may be oriented at an angle of B-A with respect to display 14 when anodes 42 are tilted at angle A and may therefore pass by viewer 88, whereas reflected light ray 86 from anodes that are not tilted would be reflected directly at viewer 88. The ability of tilted anodes to redirect undesired specular reflections from display 14 so that reflected ambient light 84 is not reflected towards viewer 88 allows display 14 to be used in environments with potentially bright ambient light sources 80 without risk of interference from reflected ambient light.

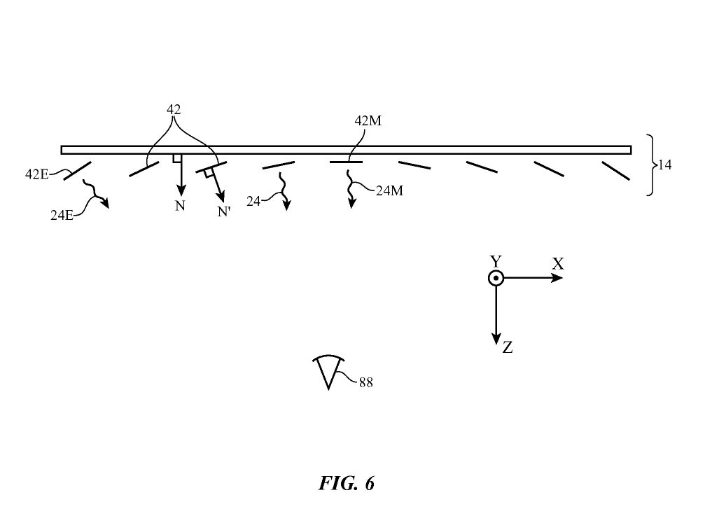

Light 24 is emitted outwards from each anode 42 along surface normal N′. If desired, anodes 42 may be tilted by different angles A at different positions across the surface of display 14. As shown in FIG. 6, for example, anodes near the edge of display 14 such as anode 42E may be tilted at an angle A that is larger than anodes near the middle of display 14 such as anode 42M. With this type of configuration, edge diodes will emit light 24E that is directed towards a viewer such as viewer 88 who is located in front of the center of display 14 and light-emitting diodes in the center of display 14 will emit light 24M that is directed towards this viewer. This type of tilting arrangement maximizes light-emitting diode emission efficiency while minimizing color shifts due to off-axis viewing.

Anodes 42 may be tilted (rotated) in one dimension or two dimensions. For example, each anode 42 may be rotated by a different angle A about axis Y as a function of the position of that anode 42 along lateral dimension X or each anode 42 may be rotated by different angles about both axes X and Y as a function of the position of that anode 42 in both lateral dimension X and lateral dimension Y (e.g., to accommodate large displays 14 in which the upper and lower edges of the display are far apart from each other as well as the left and right edges). In the example of FIG. 6, anodes 42 are have been rotated by varying amounts about axis Y. As shown in FIG. 6, anodes 42 to the left of viewer 88 are tilted inwardly to the right and anodes 42 to the right of viewer 88 are tilted inwardly to the left. Emitted light 24 is therefore directed towards viewer 88, regardless of the location of the light-emitting diode producing that emitted light. For example, light that is emitted from diodes along the left edge of display 14 such as emitted light 24E will be directed towards viewer 88 (or at least more towards viewer 88 than in a display without tilted anodes) even though these diodes are not located in the center of display 14 such as the diode associated with anode 42M.

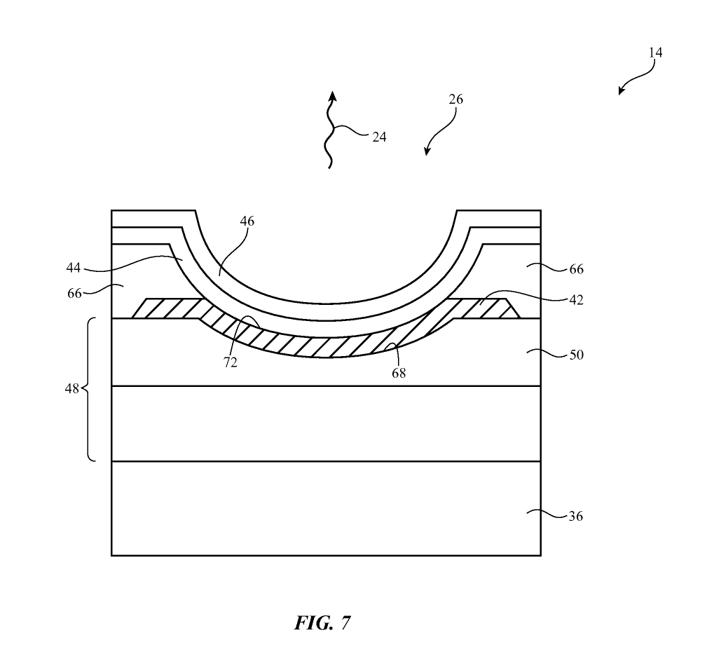

Another way in which to minimize intensity and color shifts when viewing off-axis pixels involves the use of curved anode structures of the type shown in FIG. 7. As shown in FIG. 7, anode 42 may have a curved cross-sectional shape. Anode 42 may, for example, be bowed inwardly towards the underlying thin-film transistor structures on display 14 and towards display substrate 36. Configurations in which anodes 42 bow outwardly and/or have more complex non-planar surfaces may also be used. The inwardly curved shape of anode 42 in the configuration of FIG. 7 is merely an example.

As shown in FIG. 7, dielectric layer 50 may have a curved surface 68 under anode 42. Anode 42 may be formed in an opening in pixel definition layer 66 and may be supported on curved surface 68 of dielectric layer 50 under the opening in pixel definition layer 66. This gives anode 42 a curved upper surface such as curved surface 72. Emissive material 44 and cathode 46 will likewise be curved when deposited on curved surface 72. The amount of curvature of anode 42 may be characterized by the ratio R of its depth to width. The value of R may be 0.1, 0.2, 0.3, 0.05-0.4, 0.01 to 0.5, 0.1 to 0.3, less than 0.4, more than 0.1, 0.1 to 0.35, or other suitable value. Larger values of R (e.g., 0.3) may exhibit lower specular reflections and better off-axis intensity shift and color shift performance than lower values of R (e.g., 0.1), but lower values of R may be used, if desired (e.g., to help minimize process complexity). Curved anodes may be implemented by forming dielectric layer 50 from a photoimageable polymer (e.g., by forming curved surface 68 using a graytone photomask and photolithographic patterning techniques). Curved depressions and, if desired, tilted depressions in the surface of dielectric layer 50 may also be formed using other fabrication techniques. The use of graytone masks and photolithographic fabrication techniques to form pixels with anodes 42 that are not parallel with the surface of substrate 36 is merely illustrative.

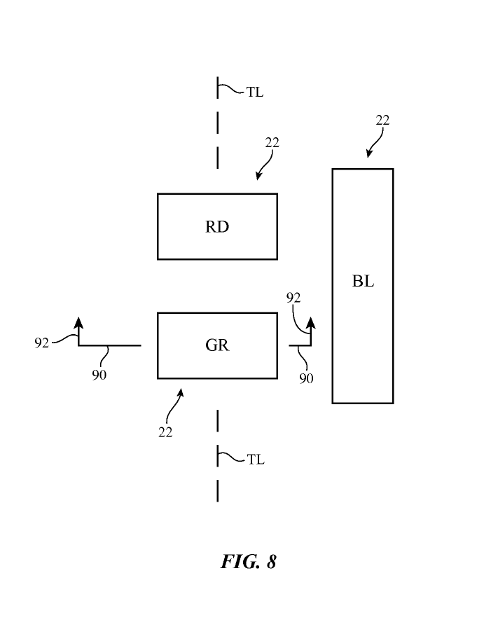

Pixels 22 may include pixels of different colors. For example, pixels 22 may include red pixels having red light-emitting diodes that emit red light, green pixels that have green light-emitting didoes that emit green light, and blue pixels that have blue light-emitting diodes that emit blue light. FIG. 8 is a top view of a portion of display 14 showing how an illustrative set of red RD, blue BL, and green GR light-emitting diodes may be arranged on the surface of display 14. This type of configuration may be used to provide the blue diodes with more anode area (e.g., to lower blue diode current levels to accommodate blue emissive material that is more sensitive to aging effects than red and green emissive material).

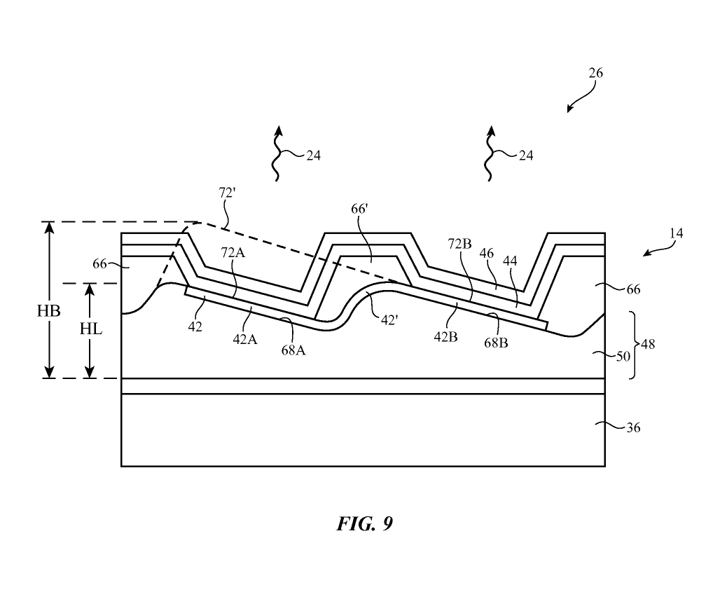

When tilting anodes 42, it may be desirable to limit the maximum amount of tilt in each anode, thereby helping to maintain planarity in display 14. Consider, as an example, a configuration in which it is desired to tilt the anodes of the red, green, and blue pixels of FIG. 8 about tilt axis TL. In this type of configuration, tilt axis TL runs perpendicular to the longitudinal axes of the green and red anodes, so the green and red anodes will potentially exhibit a large amount of height difference between their lowest and highest portions when tilted. To limit the maximum amount of vertical height between the lowest and highest portions of the green and red anodes as the green and red anodes are tilted about tilt axis TL, the green and red anodes may be provided with multiple tilted segments. FIG. 9 is a cross-sectional side view of a diode with this type of segmented anode configuration. The cross-sectional side view of FIG. 9 is taken along line 90 of FIG. 8 as viewed in direction 92.

As shown in the segmented tilted anode arrangement of FIG. 9, anode 42 in diode 26 may have a first portion such as tilted segment 42A and a second portion such as tilted segment 42B. Dielectric layer 50 may be patterned to form a first tilted surface such as surface 68A and a second tilted surface such as surface 68B. Anode 42 may be formed from metal that is deposited and patterned on surfaces 68A and 68B. Anode portion 42A is formed on tilted surface 68A so surface 72A of anode 42 is tilted. Anode portion 42B is formed on tilted surface 68B so surface 72B of anode 42 is also tilted. The angle of tilt of portions 42A and 42B may be the same or may be different.

By using two tilted segments for anode 42, the maximum height excursion of anode 42 may be minimized. In the absence of the segmented anode arrangement of FIG. 9, upper surface 72′ of anode 42 would exhibit a height excursion of HB (i.e., the difference in height between the tallest portion of anode 42 and the lowest portion of anode 42 would be HB). When anode 42 is segmented into portions 42A and 42B, each segment is narrower and therefore exhibits a smaller height excursion HL. Because HL is less than HB, the use of a segmented tilted anode arrangement may help reduce surface height excursions and may facilitate fabrication. There may be any suitable number of separately tilted portions of each anode 42. The use of two tilted portions 42A and 42B in the example of FIG. 9 is merely illustrative.

In the example of FIG. 9, pixel definition layer 66 has a central portion 66′ that lies between first anode segment 42A and second anode segment 42B. Segments 42A and 42B are connected by central connecting anode portion 42′. Central anode portion 42′ may have portions that reflect ambient light towards viewer 88. It may be desirable to suppress these reflections by ensuring that pixel definition layer portion 66′ overlaps anode portion 42′. Alternatively, light emission may be maximized by omitting portion 66′ of pixel definition layer 66.

Tilted anodes 42 may be formed by using a photoimageable polymer for forming dielectric layer 50 and by patterning the photoimageable polymer through a graytone mask, thereby forming tilted (or curved) surfaces such as tilted surfaces 68A and 68B of diode 26 of FIG. 9. If desired, tilted or curved surfaces such as tilted surfaces 68A and 68B of FIG. 9, tilted surface 68 of FIG. 4, curved surface 68 of FIG. 7, etc. may be formed by placing underlying metal structures in locations that cause dielectric layer 50 to exhibit tilted (or curved) surface portions.

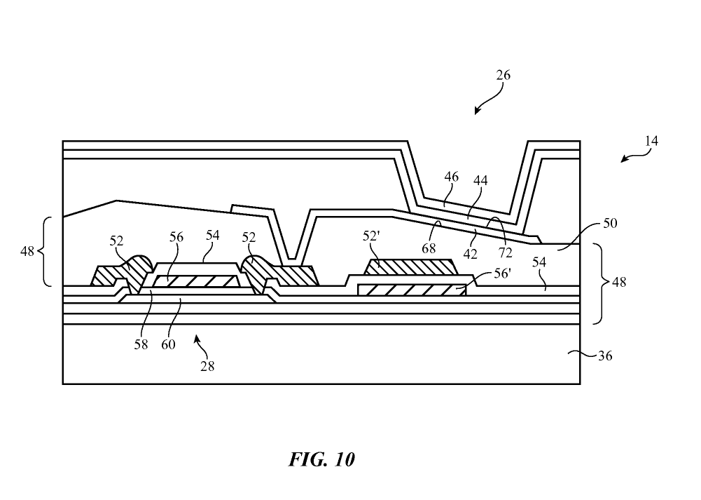

Consider, as an example, the arrangement of FIG. 10. In the configuration of FIG. 10, a portion of source-drain layer 52 is being used to form source and drain terminals for transistor 28 and a portion of gate layer 56 is being used to form a gate terminal for transistor 28. Portion 52′ of source-drain layer 52 and portion 56′ of gate layer 56 serve at tilt-inducing structures and are being used to create a step in height in the structures of thin-film transistor layers 48. This step in height gives rise to tilted surface 68 in dielectric layer 50 and thereby tilts anode 42.

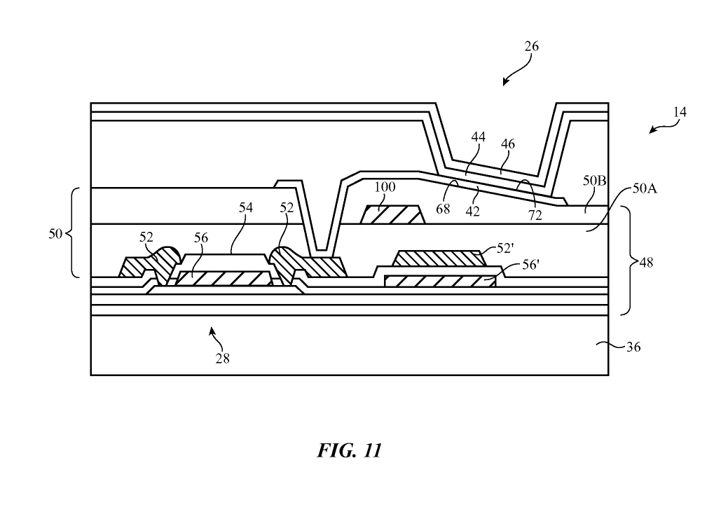

In the illustrative configuration of FIG. 11, dielectric layer 50 has been formed from two dielectric layers 50A and 50B. Layers 50A and 50B may be formed from photoimageable polymers or other suitable dielectrics. Layer 50A may be used as a planarization layer. If desired, metal structures 56′ and 52′ may be formed under layer 50A to impart tilt to the surface of layer 50A. After layer 50A has been deposited, additional tilt-inducing structures such as structure 100 may be formed on the surface of layer 50A. Structure 100 may be a photolithographically patterned portion of an additional layer of metal, may be a photolithographically patterned polymer structure, may be a photolithographically patterned dielectric layer, may be a structure that is patterned using non-photolithographic techniques, or may be any additional layer of material that helps impart a desired tilt to surface 68 of polymer layer 50B. As shown in FIG. 11, the tilt in surface 68 that is created by additional structure 100 (and optional structures 52′ and/or 56′) causes anode 42 to tilt and exhibit tilted surface 72.

Although sometimes described in the context of tilted anode configurations, display 14 may have a lower electrode that is either an anode or a cathode and an upper electrode (counter electrode) that is either a cathode or anode, respectively. Both the anode and the cathode will, in general, be tilted (or curved). The use of configurations in which anode 42 is located below cathode 46 is merely illustrative.

The foregoing is merely illustrative and various modifications can be made by those skilled in the art without departing from the scope and spirit of the described embodiments. The foregoing embodiments may be implemented individually or in any combination.

1. A display, comprising:
a substrate having a substrate surface;
thin-film transistor circuitry on the substrate; and
an array of organic light-emitting diodes on the thin-film transistor circuitry, wherein at least one organic light-emitting diode in the array has a first electrode, a second electrode, and emissive material between the first electrode and the second electrode, wherein the first electrode has a first planar electrode surface that is not parallel to the substrate surface.

2. (canceled)

3. The display defined in claim 1 wherein the thin-film transistor circuitry includes a polymer layer and wherein the first electrode is formed on the polymer layer.

4. (canceled)

5. (canceled)

6. The display defined in claim 1 wherein the first planar electrode surface is tilted with respect to the substrate surface.

7. The display defined in claim 6 wherein the thin-film transistor circuitry includes a polymer layer and wherein the first electrode is formed on the polymer layer.

8. The display defined in claim 7 wherein the polymer layer has a polymer layer surface, wherein the polymer layer overlaps tilt-inducing structures that tilt portions of the polymer layer surface at a non-zero angle with respect to the substrate surface, and wherein the first electrode is formed on the tilted portions of the polymer layer surface.

9. The display defined in claim 8 wherein the thin-film transistor circuitry includes a source-drain metal layer and wherein the tilt-inducing structures are formed from the source-drain metal layer.

10. The display defined in claim 8 wherein the thin-film transistor circuitry includes a gate metal layer and wherein the tilt-inducing structures are formed from a portion of the gate metal layer.

11. The display defined in claim 8 wherein the thin-film transistor circuitry includes a source-drain metal layer and a gate metal layer and wherein the tilt-inducing structures are formed from overlapping portions of the source-drain metal layer and the gate metal layer.

12. The display defined in claim 1 wherein the first planar electrode surface is tilted with respect to the substrate surface, wherein the thin-film transistor circuitry includes first and second polymer layers, wherein the first electrode is formed on the second polymer layer, wherein the thin-film transistor circuitry includes a source-drain metal layer and a gate metal layer, wherein the first polymer layer is interposed between the gate metal layer and the source-drain metal layer, wherein the display further comprises an additional layer that at least partly overlaps the source-drain metal layer and the gate metal layer and that helps tilt the first electrode, and wherein the second polymer layer is interposed between the source-drain metal layer and the additional layer.

13. The display defined in claim 12 wherein the additional layer is formed from a metal layer that is separate from the source-drain metal layer and the gate metal layer.

14. The display defined in claim 6 wherein the first electrode has at least a first tilted portion that is tilted at a given angle with respect to the substrate surface and a second tilted portion that is tilted at the given angle with respect to the substrate surface.

15. The display defined in claim 14 wherein the first electrode has a portion between the first and second tilted portions that joins the first and second tilted portions and that is not tilted at the given angle with respect to the substrate surface.

16. The display defined in claim 1 wherein each organic light-emitting diode in the array has a first electrode, a second electrode, and emissive material between the first electrode and the second electrode, wherein the substrate surface has lateral dimensions, and wherein the first electrodes have planar portions that are tilted with respect to the substrate surface by amounts that vary as a function of distance across substrate surface in at least one of the lateral dimensions.

17. The display defined in claim 1 wherein each organic light-emitting diode in the array has a first electrode, a second electrode, and emissive material between the first electrode and the second electrode, wherein the substrate surface as first and second lateral dimensions, and wherein the first electrodes have planar portions that are tilted with respect to the substrate surface by amounts that vary as a function of position on the substrate surface along both the first and second lateral dimensions.

18. A method for forming a display on a substrate that has a substrate surface, comprising:
forming thin-film transistor circuitry on the substrate that includes a polymer layer with polymer layer surface portions that are not parallel to the substrate surface; and
forming an array of light-emitting diodes on the polymer layer that have first and second electrodes, wherein the first electrodes are on the polymer layer surface portions that are not parallel to the substrate surface such that the first electrodes have portions that are not parallel to the substrate surface, where the portions that are not parallel to the substrate are all curved inward towards the thin-film transistor circuitry.

19. The method defined in claim 18 wherein forming the thin-film transistor circuitry comprises photolithographically patterning the polymer layer in the thin-film transistor circuitry with a graytone photolithographic mask to produce the polymer layer surface portions that are not parallel to the substrate surface.

20. An organic light-emitting diode display, comprising:
a substrate having a substrate surface;
thin-film transistor circuitry on the substrate; and
an array of organic light-emitting diodes on the thin-film transistor circuitry, wherein at least one organic light-emitting diode in the array has a first electrode, a second electrode, and emissive material between the first and second electrodes and wherein the first electrode has a first electrode surface, wherein the first electrode surface has a portion that is in direct contact with the emissive material, wherein the entire portion that is direct contact with the emissive material is planar and is tilted at a non-zero angle with respect to the substrate surface.

21. The display defined in claim 20 wherein each organic light-emitting diode in the array has a first electrode, a second electrode, and emissive material between the first electrode and the second electrode, wherein each of the first electrodes is tilted by an amount that varies depending on where that first electrode is located on the substrate.

22. The display defined in claim 20 wherein the first electrode has first and second tilted segments that each are tilted at the non-zero angle with respect to the substrate surface.

23. The display defined in claim 15, wherein the first tilted portion is planar, and wherein the second tilted portion is planar.

24. The display defined in claim 1, wherein the first electrode has a portion that is in direct contact with the emissive material, wherein the entire portion that is direct contact with the emissive material is planar and tilted at a non-zero angle with respect to the substrate surface.

25. The method defined in claim 18, wherein none of the portions that are not parallel to the substrate are curved away from the thin-film transistor circuitry.
